(19) United States
(12) Patent Application Publication
(10) Pub. No.: US 2026/0114321 A1
(43) Pub. Date: Apr. 23, 2026

(54) STRUCTURE AND FORMATION METHOD OF PACKAGE WITH INTERPOSERS

(71) Applicant: Taiwan Semiconductor Manufacturing Company, Ltd., Hsinchu (TW)

(72) Inventors: Wei-Cheng LI, Yunlin County (TW); Meng-Liang LIN, Hsinchu (TW); Hsien-Wei CHEN, Hsinchu City (TW); Kathy Wei YAN, Hsinchu (TW)

(21) Appl. No.: 18/923,225

(22) Filed: Oct. 22, 2024

(51) Int. Cl. H01L 25/18; H01L 23/00; H01L 23/14; H01L 23/31; H01L 23/48; H01L 23/538; H01L 25/00; H10B 80/00

(52) U.S. Cl. CPC H10W 90/00; H10W 70/611; H10W 70/695; H10W 74/121; H10W 90/401; H10B 80/00; H10W 20/20; H10W 72/072; H10W 72/252; H10W 90/722; H10W 90/724

(57) ABSTRACT

A package structure and a formation method of a package structure are provided. The method includes forming a semiconductor interposer and bonding a chip-containing structure to the semiconductor interposer. The method also includes bonding a memory-containing structure to the semiconductor interposer. The method further includes bonding the semiconductor interposer to a redistribution interposer after the chip-containing structure and the memory-containing structure are bonded to the semiconductor interposer. The redistribution interposer has multiple organic layers.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A package structure not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor chips. These relatively new types of packaging technologies for semiconductor chips face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1F are cross-sectional views of various stages of a process for forming a portion of a package structure, in accordance with some embodiments.

FIGS. 2A-2G are cross-sectional views of various stages of a process for forming a portion of a package structure, in accordance with some embodiments.

FIG. 3 is a cross-sectional view of a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher of what is specified, such as 95% or higher, especially 99% or higher, including 100%. Furthermore, terms such as “substantially parallel” or “substantially perpendicular” are to be interpreted as not to exclude insignificant deviation from the specified arrangement and may include for example deviations of up to 10 degrees. The word “substantially” does not exclude “completely” e.g. a composition which is “substantially free” from Y may be completely free from Y.

Terms such as “about” in conjunction with a specific distance or size are to be interpreted so as not to exclude insignificant deviation from the specified distance or size and may include for example deviations of up to 10%. The term “about” in relation to a numerical value x may mean x±5 or 10%.

Some embodiments of the disclosure are described. Additional operations can be provided before, during, and/or after the stages described in these embodiments. Some of the stages that are described can be replaced or eliminated for different embodiments. Additional features can be added to the semiconductor device structure and/or the package structure. Some of the features described below can be replaced or eliminated for different embodiments. Although some embodiments are discussed with operations performed in a particular order, these operations may be performed in another logical order.

Embodiments of the disclosure may relate to three-dimensional (3D) packaging or 3D-IC devices. Other features and processes may also be included. For example, testing structures may be included to aid in the verification testing of the 3D packaging or 3D-IC devices. The testing structures may include, for example, test pads formed in a redistribution layer or on a substrate that allows the testing of the 3D packaging or 3D-IC, the use of probes and/or probe cards, and the like. The verification testing may be performed on intermediate structures as well as the final structure. Additionally, the structures and methods disclosed herein may be used in conjunction with testing methodologies that incorporate intermediate verification of known good chips to increase the yield and decrease costs.

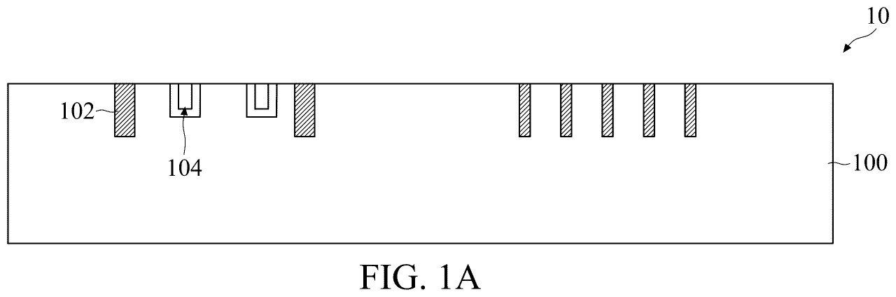

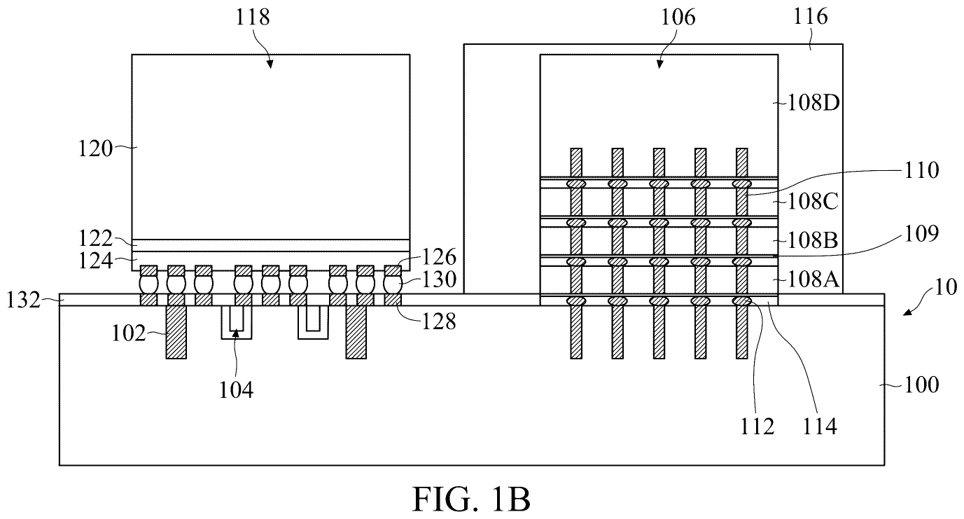

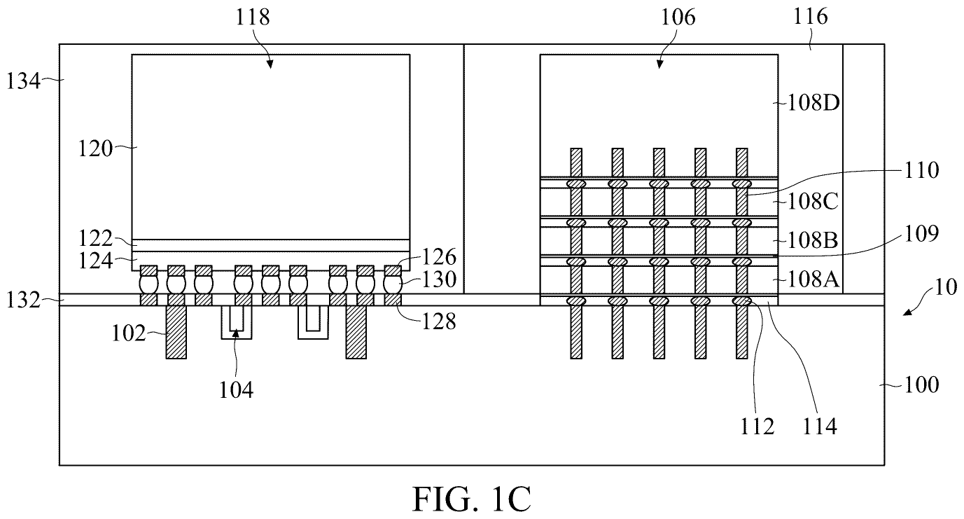

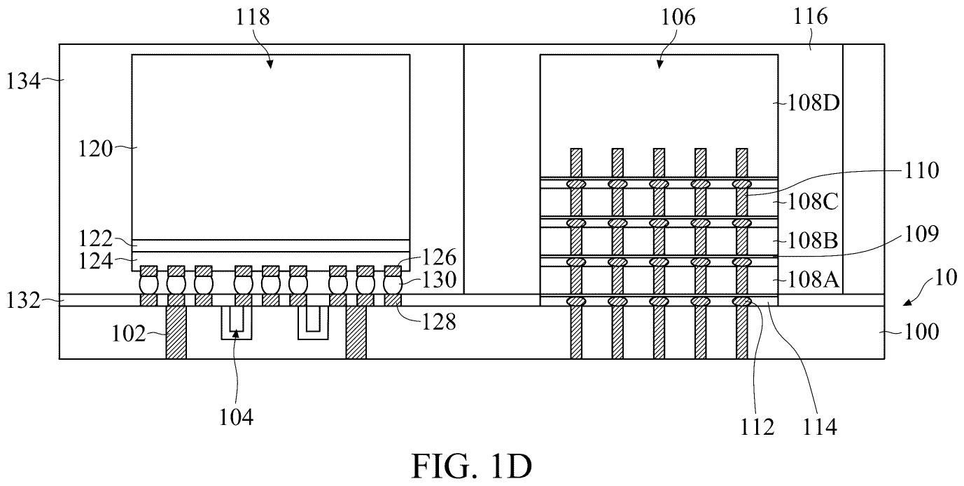

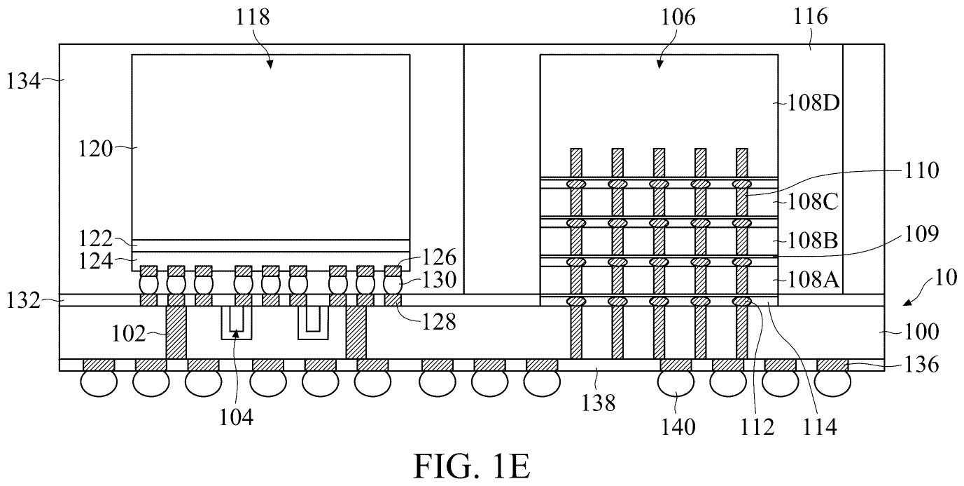

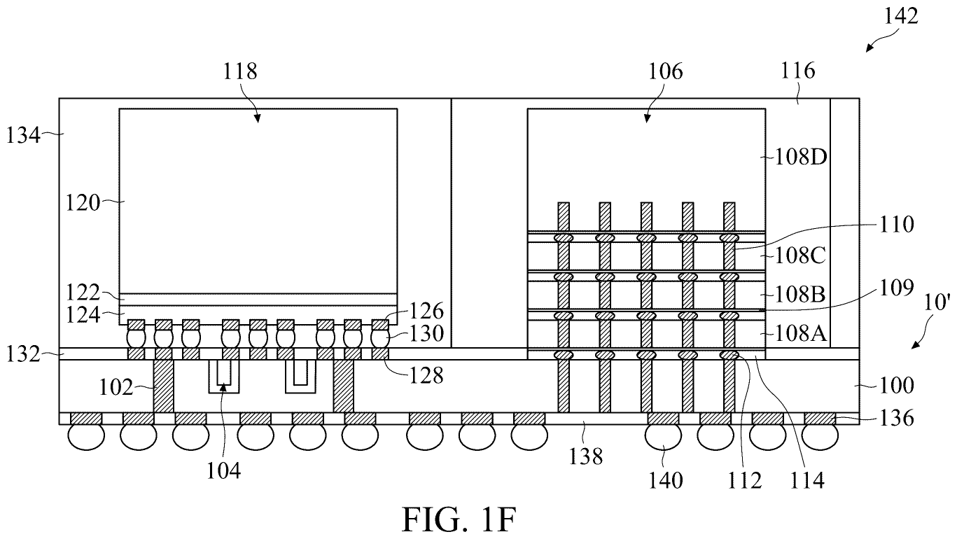

FIGS. 1A-1F are cross-sectional views of various stages of a process for forming a package structure, in accordance with some embodiments. As shown in FIG. 1A, a semiconductor wafer 10 is provided or received. The semiconductor wafer 10 includes a semiconductor substrate 100. The semiconductor substrate 100 may be made of or include silicon, germanium, silicon germanium, another suitable semiconductor material, or a combination thereof.

In some embodiments, multiple conductive structures 102 are formed in the semiconductor substrate 100, as shown in FIG. 1A. The conductive structures 102 may function as conductive vias. In some embodiments, the semiconductor substrate 100 is partially removed to form multiple openings. The openings may be formed using one or more photolithography processes and one or more etching processes.

In some embodiments, a dielectric layer is deposited over the semiconductor substrate 100, as shown in FIG. 1A in accordance with some embodiments. The dielectric layer extends along the sidewalls and bottoms of the openings. The dielectric layer may be used to electrically isolate the semiconductor substrate 100 and the conductive structures 102 that will be formed later. The dielectric layer may be made of or include silicon oxide, silicon oxynitride, silicon nitride, carbon-containing silicon oxide, carbon-containing silicon oxynitride, carbon-containing silicon nitride, silicon carbide, one or more other suitable materials, or a combination thereof. The dielectric layer may be deposited using a chemical vapor deposition (CVD) process, an atomic layer deposition (ALD) process, a thermal oxidation process, one or more other applicable processes, or a combination thereof.

In some embodiments, a conductive material is then deposited over the semiconductor substrate 100 to partially or completely fill the openings of the semiconductor substrate 100. The conductive material may be made of or include copper, aluminum, cobalt, tungsten, gold, titanium, platinum, one or more other suitable materials, or a combination thereof. The conductive material may be deposited using a physical vapor deposition (PVD) process, a CVD process, an ALD process, an electroplating process, an electroless plating process, one or more other applicable processes, or a combination thereof.

Afterwards, the conductive material and the dielectric layer are partially removed. As a result, the remaining portions of the conductive material form the conductive structures 102, as shown in FIG. 1A. A planarization process may be used to remove the portions of the conductive material outside of the openings. The remaining portions of the conductive material in the openings form the conductive structures 102. The planarization process may include a chemical mechanical polishing (CMP) process, a grinding process, an etching process, a dry polishing process, one or more other applicable processes, or a combination thereof.

In some embodiments, multiple capacitor elements 104 are formed in the semiconductor substrate 100, as shown in FIG. 1A. The capacitor elements 104 may be deep trench capacitors. In some embodiments, the semiconductor substrate 100 is partially removed to form multiple trenches. Afterwards, a first electrode layer, a capacitor dielectric layer, and a second electrode layer are formed in the trenches. As a result, the capacitor elements 104 are formed. The formation of the capacitor elements 104 may involve one or more patterning processes, multiple deposition processes, and one or more planarization processes.

As shown in FIG. 1B, an interconnection structure is formed over the semiconductor substrate 100 and the conductive structures 102, in accordance with some embodiments. The interconnection structure includes multiple dielectric layers and multiple conductive features. A dielectric layer 132 of the dielectric layers is shown in FIG. 1B. The conductive features may include conductive lines, conductive vias, and/or other suitable conductive structures such as conductive pads 128 shown in FIG. 1B. Some of the conductive pads 128 are electrically connected to the conductive structures 102 and/or the capacitor elements 104.

The dielectric layer 132 may be made of or include silicon oxide, silicon oxynitride, silicon nitride, carbon-containing silicon oxide, carbon-containing silicon oxynitride, carbon-containing silicon nitride, silicon carbide, one or more other suitable materials, or a combination thereof. The conductive pads 128 may be made of or include copper, aluminum, cobalt, tungsten, gold, titanium, platinum, one or more other suitable materials, or a combination thereof. The formation of the interconnection structure may involve multiple deposition processes, multiple patterning processes, and multiple planarization processes.

As shown in FIG. 1B, a memory-containing structure 106 and a chip-containing structure 118 are bonded to the semiconductor wafer 10, in accordance with some embodiments. In some embodiments, the memory-containing structure 106 is bonded to the semiconductor wafer 10 before the chip-containing structure 118. In some other embodiments, the memory-containing structure 106 is bonded to the semiconductor wafer 10 after the chip-containing structure 118.

In some embodiments, the memory-containing structure 106 includes multiple memory chips 108A, 108B, 108C and 108D that are vertically stacked. In some embodiments, each of the memory chips 108A, 108B, 108C and 108D includes memory devices such as dynamic random access memory (DRAM) devices, static random access memory (SRAM) devices, resistive random access memory (RRAM) devices, magnetoresistive random access memory (MRAM) devices, or the like.

Multiple device elements may be formed in the device portions 109 of the memory chips 108A-108D. Examples of the various device elements include transistors (e.g., metal oxide semiconductor field effect transistors (MOSFET), complementary metal oxide semiconductor (CMOS) transistors, bipolar junction transistors (BJT), or another suitable element. Various processes may be used to form the various device elements, including deposition, etching, implantation, photolithography, annealing, and/or other suitable processes.

Multiple semiconductor chips (or chiplets) such as the memory chips 108A-108D are stacked and bonded together to form electrical connections between these semiconductor chips. In some embodiments, these memory chips 108A-108D are stacked to form a high bandwidth memory (HBM) chip structure. The memory-containing structure 106 further includes a protective layer 116 laterally surrounding the memory chips 108A-108D, as shown in FIG. 1B. The protective layer 116 may be made of or includes an insulating material such as a molding material. The molding material may include a polymer material, such as an epoxy-based resin with fillers dispersed therein. The fillers may include fibers (such as silica fibers and/or carbon-containing fibers), particles (such as silica particles and/or carbon-containing particles), other suitable fillers, or a combination thereof.

In some embodiments, each of the memory chips 108A-108D includes conductive vias 110, conductive bumps 112, and a passivation layer 114 laterally surrounding the conductive bumps 112, as shown in FIG. 1B. In some embodiments, the memory chips 108A-108D includes multiple conductive vias 110. The conductive vias 110 in the memory chips 108A-108C are used as through substrate vias (TSVs). The conductive vias 110 may be used to form electrical connection between the memory chips 108A-108D and the semiconductor wafer 10. One or more dielectric layers may be formed to laterally surround each of the conductive vias 110, so as to prevent short circuiting between the conductive vias 110.

In some embodiments, the memory-containing structure 106 is bonded to the conductive structures 102 in the semiconductor substrate 100 through some of the conductive bumps 112, as shown in FIG. 1B. In some embodiments, the conductive bumps 112 are tin-containing solder bumps. The tin-containing solder bumps may further include copper, silver, gold, aluminum, lead, one or more other suitable materials, or a combination thereof. In some other embodiments, the tin-containing solder bumps are lead-free. In some embodiments, the conductive bumps 112 are micro bumps.

In some embodiments, the chip-containing structure 118 is bonded to the semiconductor wafer 10 through multiple conductive bumps 130. The conductive bumps 130 may include tin-containing solder bumps. The tin-containing solder bumps may include tin and other materials such as copper, silver, gold, aluminum, lead, another suitable material, or a combination thereof. In some embodiments, the conductive bumps 130 are lead-free solder bumps. In some embodiments, the conductive bumps 130 are micro bumps.

In some embodiments, the chip-containing structure 118 is a logic control chip structure that includes multiple logic control device elements. The chip-containing structure 118 may include a semiconductor substrate portion 120, a device portion 122, and an interconnection structure 124. The semiconductor substrate portion 120 may include silicon or other elementary semiconductor materials such as germanium. In some embodiments, the semiconductor substrate portion 120 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate portion 120 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

Multiple device elements are formed in and/or on the device portion 122. Examples of the various device elements include transistors (e.g., metal oxide semiconductor field effect transistors (MOSFET), complementary metal oxide semiconductor (CMOS) transistors, bipolar junction transistors (BJT), or another suitable element. Various processes may be used to form the various device elements, including deposition, etching, implantation, photolithography, annealing, and/or other suitable processes.

In some embodiments, the interconnection structure 124 is formed on the device portion 122 for providing electrical connections to the device elements. The interconnection structure 124 may be a frontside interconnection structure. The interconnection structure 124 includes multiple conductive features that are surrounded by multiple dielectric layers. The conductive features may include conductive contacts, conductive lines, and conductive vias. The formation of the interconnection structure 124 may involve multiple deposition processes, multiple patterning processes, and multiple planarization processes. The device elements in the device portion 122 of the chip-containing structure 118 may be interconnected by the interconnection structure 124 to form multiple integrated circuit devices. The interconnection structure 124 includes multiple conductive features 126 that form electrical connections to the conductive bumps 130, as shown in FIG. 1B.

The chip-containing structure 118 may be a single semiconductor die that is a system-on-chip (SoC) chip, system-on-integrated-chips (SoIC), and/or a package including one or more semiconductor chips that are encapsulated or protected. For the system-on-integrated-chips, multiple semiconductor chips (or chiplets) are stacked and bonded together to form electrical connections between these semiconductor chips. In some embodiments, the semiconductor chips are system-on-chip (SoC) chips that include multiple functions. In some embodiments, the back sides of the semiconductor chips face upwards with the front sides of the semiconductor chips facing the semiconductor wafer 10.

As shown in FIG. 1C, a protective layer 134 is formed over the semiconductor substrate 100 to laterally surround and protect the chip-containing structure 118 and the memory-containing structure 106, in accordance with some embodiments. In some embodiments, the protective layer 134 is made of or includes an insulating material such as a molding material. The molding material may include a polymer material, such as an epoxy-based resin with fillers dispersed therein. The fillers may include fibers (such as silica fibers and/or carbon-containing fibers), particles (such as silica particles and/or carbon-containing particles), or a combination thereof.

In some embodiments, a molding material (such as a liquid molding material) is introduced or injected to cover the semiconductor wafer 10, the chip-containing structure 118, and the memory-containing structure 106. A thermal process is then used to cure the liquid molding material and to transform it into the protective layer 134. In some embodiments, a planarization process is performed to the protective layer 134. For example, the planarization process may include a grinding process, a CMP process, a dry polishing process, one or more other applicable processes, or a combination thereof.

As shown in FIG. 1D, the semiconductor wafer 10 is thinned, in accordance with some embodiments. As a result, the bottoms of the conductive structures 102 are exposed. A planarization process may be used to partially remove the semiconductor substrate 100 and to expose the conductive structures 102. The planarization process may include a grinding process, a CMP process, a dry polishing process, one or more other applicable processes, or a combination thereof. After the planarization process, the conductive structures 102 penetrate through the semiconductor substrate 100. The conductive structures 102 may thus function as through substrate vias (TSVs).

As shown in FIG. 1E, a backside interconnection structure that includes a dielectric layer 138 and multiple conductive features 136 is formed on the backside of the semiconductor wafer 10, in accordance with some embodiments. The conductive features 136 includes conductive pads. The conductive pads are electrically connected to the memory-containing structure 106 and/or the chip-containing structure 118 through the conductive structures 102.

Afterwards, conductive bumps 140 are formed, as shown in FIG. 1E in accordance with some embodiments. In some embodiments, the conductive bumps 140 are tin-containing solder bumps. The tin-containing solder bumps may further include copper, silver, gold, aluminum, lead, one or more other suitable materials, or a combination thereof. In some other embodiments, the tin-containing solder bumps are lead-free. In some embodiments, each of the conductive bumps 140 is wider than each of the conductive bumps 112 or each of the conductive bumps 130. In some embodiments, each of the conductive bumps 140 is larger than each of the conductive bumps 112 or each of the conductive bumps 130.

As shown in FIG. 1F, a singulation process (e.g., sawing or the like) is then used to cut through the structure shown in FIG. 1E into multiple packages. After the sawing process, a package 142 of the packages is obtained, as shown in FIG. 1F. As shown in FIG. 1F, the semiconductor substrate 100 and the conductive structures 102 may together form a semiconductor interposer 10′. In some embodiments, one or more active devices are formed in the semiconductor interposer 10′. In these cases, the semiconductor interposer 10′ may function as a base chip or an interposer chip that provide electrical communication between the memory-containing structure 106 and the chip-containing structure 118. In some embodiments, the semiconductor interposer 10′ is a large base chip that extends across the opposite edges of the chip-containing structure 118 and the opposite edges of the memory-containing structure 106. The semiconductor interposer 10′ may have a square top view profile with a side length in a range from about 10 mm to about 20 mm.

In some embodiments, the edge of the protective layer 134 is vertically aligned with the edge of the semiconductor interposer 10′, as shown in FIG. 1F. In some embodiments, the edges of the protective layer 134 and the semiconductor interposer 10′ together form a vertical sidewall.

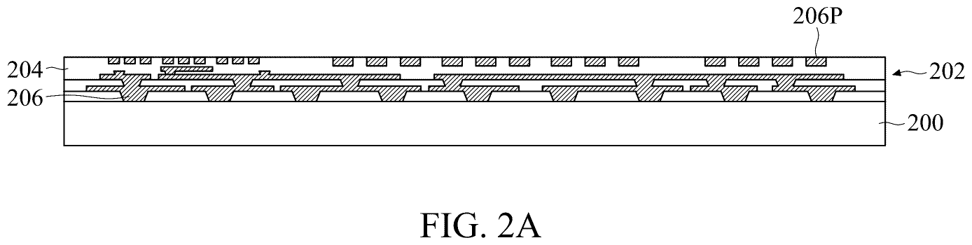

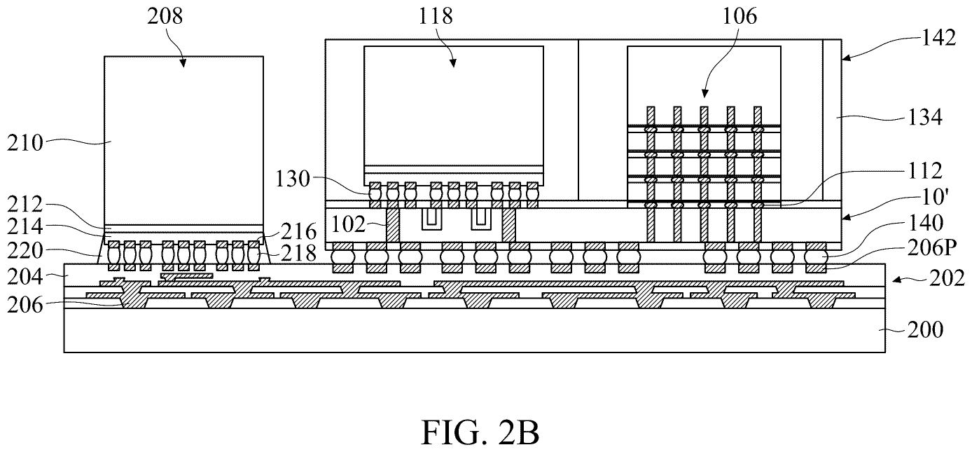

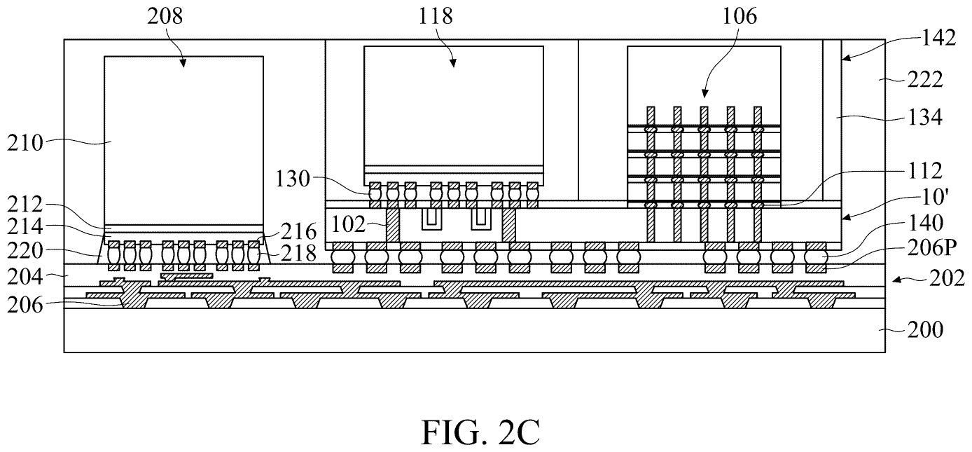

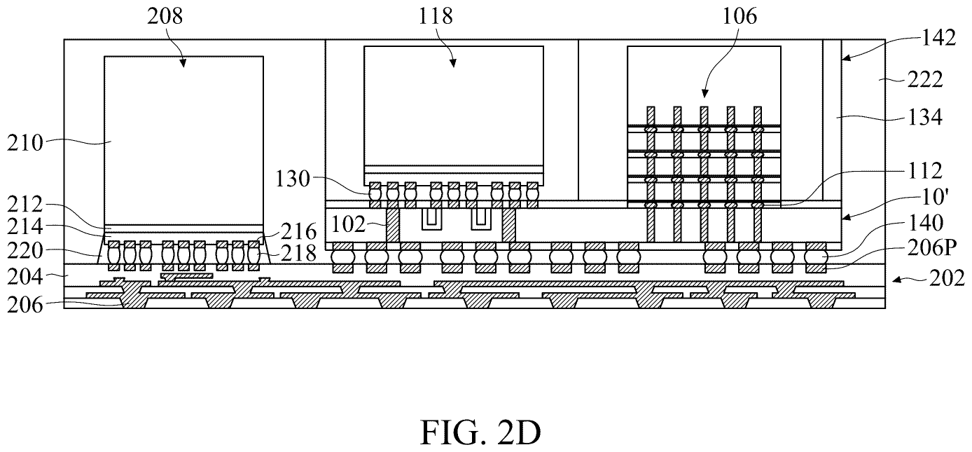

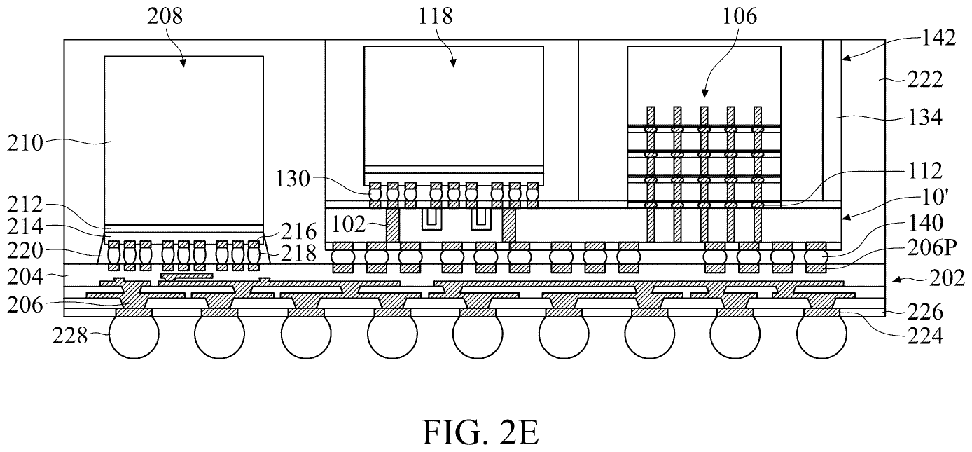

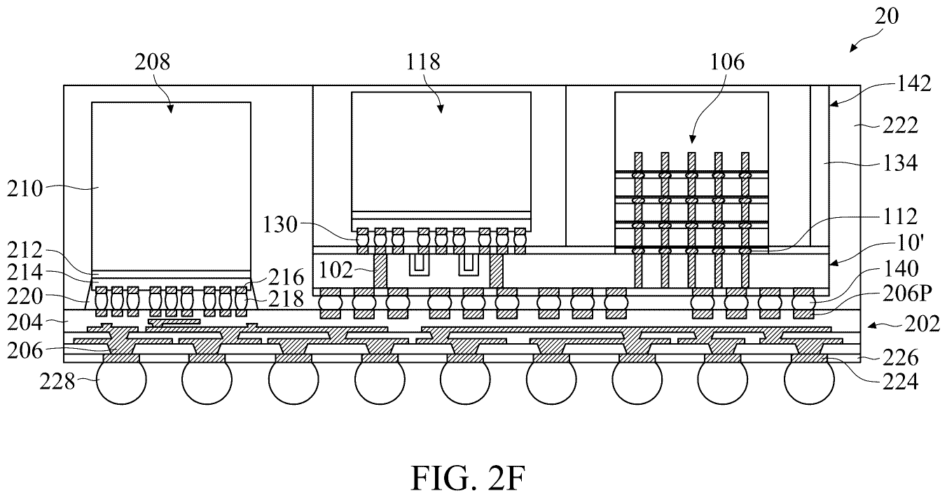

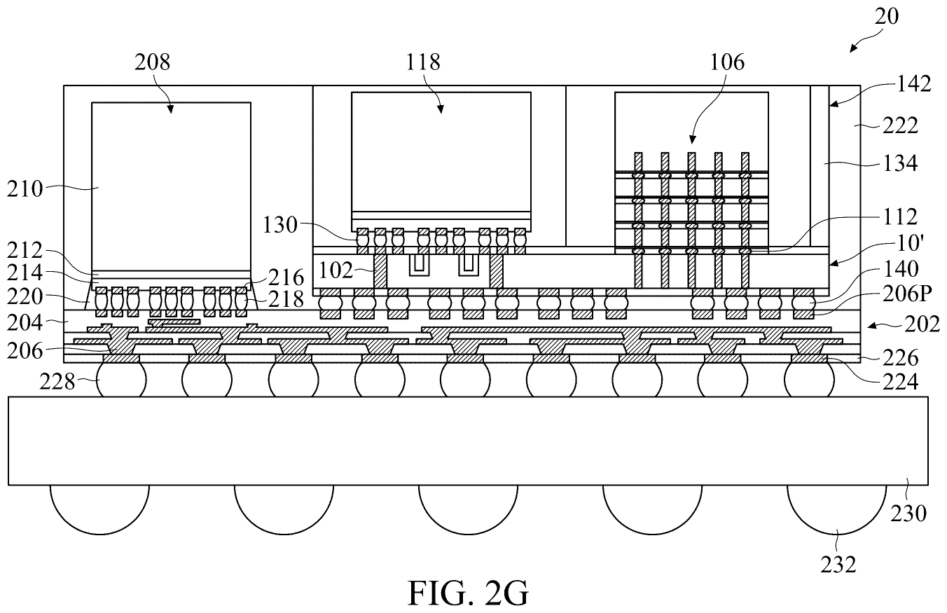

FIGS. 2A-2G are cross-sectional views of various stages of a process for forming a portion of a package structure, in accordance with some embodiments. As shown in FIG. 2A, a carrier substrate 200 is provided or received. The carrier substrate 200 is used as a support substrate during the fabrication process. In some embodiments, the carrier substrate 200 is a temporary support carrier and will be removed later.

The carrier substrate 200 may be made of or include a dielectric material, a semiconductor material, one or more other suitable materials, or a combination thereof. In some embodiments, the carrier substrate 200 is a dielectric substrate, such as a glass wafer. In some other embodiments, the carrier substrate 200 is a semiconductor substrate, such as a silicon wafer. The semiconductor substrate may be made of or include silicon, germanium, silicon germanium, another suitable semiconductor material, or a combination thereof.

As shown in FIG. 2A, a redistribution structure 202 is formed over the carrier substrate 200, in accordance with some embodiments. The redistribution structure 202 may include multiple conductive features 206 that are surrounded by multiple insulating layers 204. The conductive features 206 may include multiple conductive pads 206P that are used to receive packages to be bonded to the redistribution structure 202. The insulating layers 204 may include multiple organic layers. The organic layers are, for example, polymer-containing insulating layers. The redistribution structure 202 may function as an organic redistribution interposer.

The insulating layers 204 of the redistribution structure 202 may be made of or include one or more polymer materials. The polymer material(s) may include polybenzoxazole (PBO), polyimide (PI), epoxy-based resin, another suitable polymer material, or a combination thereof. In some embodiments, the polymer material is photosensitive. A photolithography process may therefore be used to form openings with desired patterns in the insulating layers. These openings may be used to contain some of the conductive features 206.

The conductive features 206 of the redistribution structure 202 may include conductive lines, conductive vias, and/or conductive pads. The conductive features 206 may be made of or include copper, cobalt, tin, titanium, gold, platinum, aluminum, tungsten, one or more other suitable materials, or a combination thereof. The conductive features 206 may be formed using an electroplating process, an electroless plating process, another applicable process, or a combination thereof. The formation of the conductive features may further involve one or more etching processes and one or more planarization processes.

As shown in FIG. 2B, multiple elements including a chip-containing structure 208 and a package 142 the same as or similar to the package 142 shown in FIG. 1F are disposed over the redistribution structure 202, in accordance with some embodiments. In some embodiments, before the elements are disposed, a testing operation is performed to the redistribution structure 202 to ensure the quality and reliability of the redistribution structure 202.

In some embodiments, the chip-containing structure 208 is bonded onto the redistribution structure 202 through conductive bumps 218. The conductive bumps 218 may include tin-containing solder bumps. The tin-containing solder bumps may include tin and other materials such as copper, silver, gold, aluminum, lead, another suitable material, or a combination thereof. In some embodiments, the conductive bumps 218 are lead-free solder bumps.

In some embodiments, the chip-containing structure 208 is a logic control chip structure that includes multiple logic control device elements. The chip-containing structure 208 may include a semiconductor substrate portion 210, a device portion 212, and an interconnection structure 214. The semiconductor substrate portion 210 may include silicon or other elementary semiconductor materials such as germanium. In some embodiments, the semiconductor substrate portion 210 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate portion 210 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

Multiple device elements are formed in and/or on the device portion 212. Examples of the various device elements include transistors (e.g., metal oxide semiconductor field effect transistors (MOSFET), complementary metal oxide semiconductor (CMOS) transistors, bipolar junction transistors (BJT), or another suitable element. Various processes may be used to form the various device elements, including deposition, etching, implantation, photolithography, annealing, and/or other suitable processes.

In some embodiments, the interconnection structure 214 is formed on the device portion 212 for providing electrical connections to the device elements. The interconnection structure 214 may be a frontside interconnection structure. The interconnection structure 214 includes multiple conductive features that are surrounded by multiple dielectric layers. The conductive features may include conductive contacts, conductive lines, and conductive vias. The formation of the interconnection structure 214 may involve multiple deposition processes, multiple patterning processes, and multiple planarization processes. The device elements in the device portion 212 of the chip-containing structure 208 may be interconnected by the interconnection structure 214 to form multiple integrated circuit devices. The interconnection structure 214 includes multiple conductive features 216 that form electrical connections to the conductive bumps 218, as shown in FIG. 2B. In some embodiments, an underfill structure 220 is formed to laterally surround and to protect the conductive bumps 218, as shown in FIG. 2B.

The chip-containing structure 208 may be a single semiconductor chip such as a system-on-chip (SoC) chip, system-on-integrated-chips (SoIC), and/or a package including one or more semiconductor dies that are encapsulated or protected. For the system-on-integrated-chips, multiple semiconductor dies (or chiplets) are stacked and bonded together to form electrical connections between these semiconductor dies. In some embodiments, the semiconductor dies are system-on-chip (SoC) chips that include multiple functions. In some embodiments, the back sides of the semiconductor dies face upwards with the front sides of the semiconductor dies facing the redistribution structure 202.

As shown in FIG. 2B, the package 142 is bonded onto the redistribution structure 202 through multiple conductive bumps 140, in accordance with some embodiments. The package 142 may be the same as or similar to the structure shown in FIG. 1F. In some embodiments, the package 142 is bonded to the redistribution structure 202 before the chip-containing structure 208. In some other embodiments, the package 142 is bonded to the redistribution structure 202 after the chip-containing structure 208.

As shown in FIG. 2C, a protective layer 222 is formed over the redistribution structure 202 to laterally surround and protect the chip-containing structure 208, the chip-containing structure 118, the memory-containing structure 106, and the semiconductor interposer 10′, in accordance with some embodiments. In some embodiments, the protective layer 222 is in physical contact with the redistribution structure 202. In some embodiments, an interface between the protective layers 134 and 222 is vertically aligned with an interface between the protective layer 222 and the semiconductor interposer 10′.

In some embodiments, the protective layer 222 is made of or includes an insulating material such as a molding material. The molding material may include a polymer material, such as an epoxy-based resin with fillers dispersed therein. The fillers may include fibers (such as silica fibers and/or carbon-containing fibers), particles (such as silica particles and/or carbon-containing particles), or a combination thereof.

In some embodiments, a molding material (such as a liquid molding material) is introduced or injected to cover the redistribution structure 202, the chip-containing structure 208, and the package 142. In some embodiments, a thermal process is then used to cure the liquid molding material and to transform it into the protective layer 222.

In some embodiments, a planarization process is performed to the protective layer 222 to improve the flatness of the protective layer 222. For example, the planarization process may include a grinding process, a CMP process, a dry polishing process, one or more other applicable processes, or a combination thereof. In some embodiments, after the planarization process, the top surface of the protective layer 222 is substantially level with the surface of the protective layer 134.

As shown in FIG. 2D, the carrier substrate 200 is removed, in accordance with some embodiments. As a result, the surface of the redistribution structure 202 that is originally covered by the carrier substrate 200 is exposed. In some embodiments, a carrier tape is used to assist in the removal of the carrier substrate 200 and the subsequent processes.

As shown in FIG. 2E, an insulating layer 226 and multiple conductive features 224 are formed, in accordance with some embodiments. The material and formation method of the insulating layer 226 may be the same as or similar to those of the insulating layers 204. The conductive features 224 may function as conductive pads.

As shown in FIG. 2E, conductive bumps 228 are formed over the exposed surface of the redistribution structure 202, as shown in FIG. 2E in accordance with some embodiments. The conductive bumps 228 may be formed on the conductive features 224. The conductive bumps 228 may include tin-containing solder bumps. The tin-containing bumps may include tin and other materials such as copper, silver, gold, aluminum, lead, another suitable material, or a combination thereof. In some embodiments, the conductive bumps 228 are lead-free solder bumps. In some embodiments, each of the conductive bumps 228 is wider than or larger than each of the conductive bumps 218 and 140. In some embodiments, the pitch between the conductive bumps 228 is wider than the pitch between the conductive bumps 218 or 140.

As shown in FIG. 2F, a singulation process (e.g., sawing or the like) is then used to cut through the structure shown in FIG. 2E into multiple package structures. After the sawing process, a package structure 20 of the package structures is obtained, as shown in FIG. 2F in accordance with some embodiments.

As shown in FIG. 2G, the package structure 20 is then bonded to a package substrate 230 through the conductive bumps 228, in accordance with some embodiments. The package substrate 230 may be a circuit substrate. In some embodiments, the package substrate 230 includes a core portion. The package substrate 230 may further includes multiple insulating layers and multiple conductive features. The conductive features may be used to route electrical signals between opposite sides of the package substrate 230. The insulating layers may be made of or include one or more polymer materials. The conductive features may be made of or include copper, aluminum, cobalt, tungsten, gold, one or more other suitable materials, or a combination thereof.

The core portion of the package substrate 230 may include organic materials such as materials that can be easily laminated. In some embodiments, the core portion may include a single-sided or double-sided copper clad laminate, epoxy, resin, glass fiber, molding compound, plastic (such as polyvinylchloride (PVC), acrylonitril, butadiene and styrene (ABS), polypropylene (PP), polyethylene (PE), polystyrene (PS), polymethyl methacrylate (PMMA), polyethylene terephthalate (PET), polycarbonates (PC), polyphenylene sulfide (PPS)), one or more other suitable elements, or a combination thereof. Conductive vias may extend through the core portion to provide electrical connections between elements disposed on either side of the core portion.

In some embodiments, the package substrate 230 further includes bonding structures 232. In some embodiments, the bonding structures 232 are solder bumps. In some embodiments, the bonding structures 232 are used for bonding with another element such as a printed circuit board.

In some embodiments, the bonding structures 232 are lead-free solder bumps. In some embodiments, each of the bonding structures 232 is wider than each of the conductive bumps 228. In some embodiments, the pitch between the bonding structures 232 is wider than the pitch between the conductive bumps 228.

As shown in FIG. 2G, the semiconductor interposer 10′ integrates the chip-containing structure 118 and the memory-containing structure 106. Due to the semiconductor interposer 10′, the interconnect loss between the chip-containing structure 118 and the memory-containing structure 106 is significantly reduced. Due to the short vertical connection paths provided by the semiconductor interposer 10′, better signal integrity and power integrity may be achieved. The performance and reliability of the package structure are greatly improved.

Many variations and/or modifications can be made to embodiments of the disclosure. In some embodiments, one or more active devices are formed in the semiconductor interposer 10′.

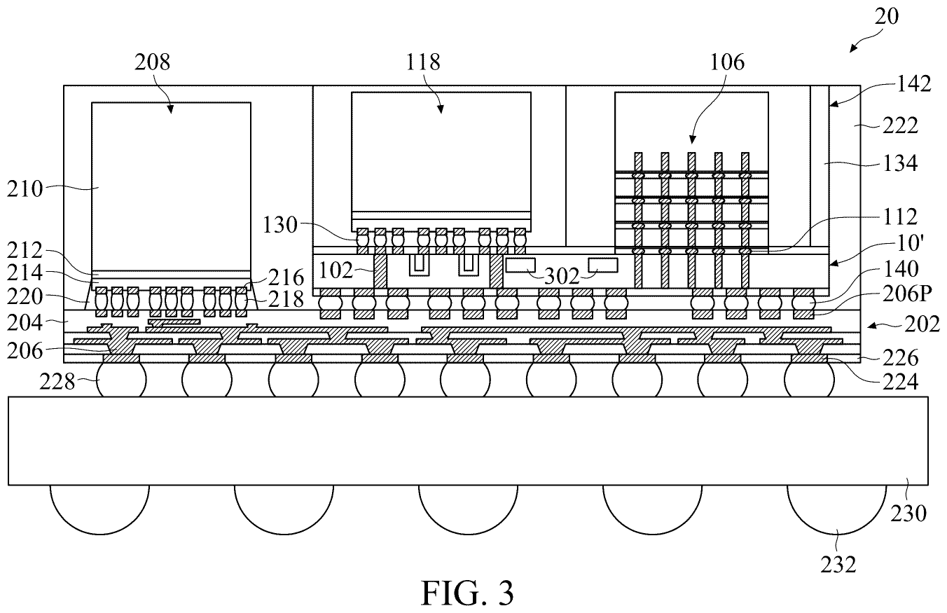

FIG. 3 is a cross-sectional view of a portion of a package structure, in accordance with some embodiments. As shown in FIG. 3, a structure that is similar to the package structure 20 shown in FIG. 2G is formed. In some embodiments, semiconductor devices 302 are formed in the semiconductor interposer 10′. In some embodiments, the semiconductor devices 302 are capable of processing and transmitting signals between the chip-containing structure 118 and the memory-containing structure 106. Since the semiconductor devices 302 are not formed in the chip-containing structure 118, more space is thus available in the chip-containing structure 118 for integrating more devices. In some embodiments, due to the assistance of the semiconductor devices 302 formed in the semiconductor interposer 10′, the operation heat generated during the operation of the chip-containing structure 118 and the memory-containing structure 106 may also be significantly reduced. The performance and reliability of the package structure are thus greatly improved.

Embodiments of this disclosure provide a package structure that features a semiconductor interposer bonded to an organic redistribution interposer. The semiconductor interposer integrates multiple chip-containing structures, such as a system-on-chip (SoC) structure and a memory-containing structure. Multiple semiconductor devices that are capable of processing and transmitting signals between the SoC structure and the memory-containing structure may be formed in the semiconductor interposer. This integration significantly reduces interconnect loss between the SoC structure and the memory-containing structure. The short vertical connection paths enabled by the semiconductor interposer enhance both signal and power integrity. Therefore, the package structure achieves greatly improved reliability and performance.

In accordance with some embodiments, a method for forming a package structure is provided. The method includes forming a semiconductor interposer and bonding a chip-containing structure to the semiconductor interposer. The method also includes bonding a memory-containing structure to the semiconductor interposer. The method further includes bonding the semiconductor interposer to a redistribution interposer after the chip-containing structure and the memory-containing structure are bonded to the semiconductor interposer. The redistribution interposer has multiple organic layers.

In accordance with some embodiments, a method for forming a package structure is provided. The method includes forming a base chip and bonding a chip-containing structure to the base chip through first tin-containing solder bumps. The method also includes bonding a memory-containing structure to the base chip through second tin-containing solder bumps. The method further includes bonding the base chip to a redistribution interposer through third tin-containing solder bumps after the chip-containing structure and the memory-containing structure are bonded to the base chip. The redistribution interposer has multiple organic layers.

In accordance with some embodiments, a package structure is provided. The package structure includes a chip-containing structure bonded to a semiconductor interposer. The package structure also includes a memory-containing structure bonded to the semiconductor interposer. The package structure further includes a redistribution interposer having multiple organic layers. The semiconductor interposer is bonded to the redistribution interposer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a package structure, comprising:
forming a semiconductor interposer;
bonding a chip-containing structure to the semiconductor interposer;
bonding a memory-containing structure to the semiconductor interposer; and
bonding the semiconductor interposer to a redistribution interposer after the chip-containing structure and the memory-containing structure are bonded to the semiconductor interposer, wherein the redistribution interposer has a plurality of organic layers.

2. The method for forming a package structure as claimed in claim 1, further comprising:
bonding a second chip-containing structure to the redistribution interposer.

3. The method for forming a package structure as claimed in claim 2, further comprising:
forming a protective layer over the redistribution interposer to laterally surround the second chip-containing structure, the chip-containing structure, the memory-containing structure, and the semiconductor interposer.

4. The method for forming a package structure as claimed in claim 3, wherein a first edge of the protective layer and a second edge of the redistribution interposer together form a vertical sidewall.

5. The method for forming a package structure as claimed in claim 3, further comprising:
forming a second protective layer over the semiconductor interposer to laterally surround the chip-containing structure and the memory-containing structure before the semiconductor interposer is bonded to the redistribution interposer.

6. The method for forming a package structure as claimed in claim 5, wherein a first interface between the second protective layer and the protective layer is vertically aligned with a second interface between the protective layer and the semiconductor interposer.

7. The method for forming a package structure as claimed in claim 1, further comprising:
forming a plurality of conductive vias in the semiconductor interposer before the chip-containing structure and the memory-containing structure are bonded to the semiconductor interposer; and
thinning the semiconductor interposer from a backside surface of the semiconductor interposer to expose the conductive vias after the chip-containing structure and the memory-containing structure are bonded to the semiconductor interposer.

8. The method for forming a package structure as claimed in claim 7, further comprising:
forming a capacitor element in the semiconductor interposer before the chip-containing structure and the memory-containing structure are bonded to the semiconductor interposer.

9. The method for forming a package structure as claimed in claim 7, further comprising:
forming a semiconductor device in the semiconductor interposer before the chip-containing structure and the memory-containing structure are bonded to the semiconductor interposer, wherein the semiconductor device transmits signals between the chip-containing structure and the memory-containing structure.

10. The method for forming a package structure as claimed in claim 1, further comprising:
sawing the semiconductor interposer before the semiconductor interposer is bonded to the redistribution interposer.

11. A method for forming a package structure, comprising:
forming a base chip;
bonding a chip-containing structure to the base chip through first tin-containing solder bumps;
bonding a memory-containing structure to the base chip through second tin-containing solder bumps; and
bonding the base chip to a redistribution interposer through third tin-containing solder bumps after the chip-containing structure and the memory-containing structure are bonded to the base chip, wherein the redistribution interposer has a plurality of organic layers.

12. The method for forming a package structure as claimed in claim 11, wherein each of the third tin-containing solder bumps is wider than each of the first tin-containing solder bumps or each of the second tin-containing solder bumps.

13. The method for forming a package structure as claimed in claim 11, further comprising:
bonding a second chip-containing structure to the redistribution interposer.

14. The method for forming a package structure as claimed in claim 13, further comprising:
forming a first protective layer laterally surrounding the chip-containing structure and the memory-containing structure; and
forming a second protective layer laterally surrounding the second chip-containing structure, the chip-containing structure, the memory-containing structure, the base chip, and the first protective layer.

15. The method for forming a package structure as claimed in claim 11, further comprising:
bonding the redistribution interposer to a package substrate through fourth tin-containing bumps, wherein each of the fourth tin-containing bumps is larger than each of the third tin-containing bumps.

16. A package structure, comprising:
a chip-containing structure bonded to a semiconductor interposer;
a memory-containing structure bonded to the semiconductor interposer; and
a redistribution interposer having a plurality of organic layers, wherein the semiconductor interposer is bonded to the redistribution interposer.

17. The package structure as claimed in claim 16, further comprising:
a second chip-containing structure bonded to the redistribution interposer.

18. The package structure as claimed in claim 17, further comprising:
a protective layer laterally surrounding the second chip-containing structure, the chip-containing structure, the memory-containing structure, and the semiconductor interposer.

19. The package structure as claimed in claim 18, further comprising:
a second protective layer laterally surrounding the chip-containing structure and the memory-containing structure, wherein the protective layer laterally surrounds the second protective layer.

20. The package structure as claimed in claim 16, further comprising:
a semiconductor device formed in the semiconductor interposer, wherein the semiconductor device transmits signals between the chip-containing structure and the memory-containing structure.
